(19) United States
(12) Patent Application Publication
(10) Pub. No.: US 2025/0089356 A1
(43) Pub. Date: Mar. 13, 2025

(54) SEMICONDUCTOR DEVICE

(71) Applicant: National Institute of Advanced Industrial Science and Technology, Tokyo (JP)

(72) Inventors: Atsushi YAO, Ibaraki (JP); Mitsuo OKAMOTO, Ibaraki (JP); Fumiki KATO, Ibaraki (JP); Hiroshi SATO, Ibaraki (JP); Shinsuke HARADA, Ibaraki (JP); Hiroshi HOZOJI, Ibaraki (JP); Shinji SATO, Ibaraki (JP)

(73) Assignee: National Institute of Advanced Industrial Science and Technology, Tokyo (JP)

(21) Appl. No.: 18/926,357

(22) Filed: Oct. 25, 2024

Related U.S. Application Data
(63) Continuation of application No. PCT/JP2023/021521, filed on Jun. 9, 2023.

(51) Int. Cl. H01L 27/092; H01L 23/522; H01L 25/065; H01L 29/16; H03K 17/0412

(52) U.S. Cl. CPC H10D 84/85; H01L 23/5228; H01L 25/065; H03K 17/04123; H10D 62/8325

(57) ABSTRACT

A change in switching time due to temperature change is suppressed. A switching circuitry is provided with a resistance component having opposite characteristics to temperature dependence of a gate current of a power transistor which is switching-controlled by the switching circuitry, and a change in a gate current due to the temperature change is suppressed by a change in the above-described resistance component due to the temperature change.

### CROSS-REFERENCE TO RELATED APPLICATIONS

The present application is a continuation application of PCT International Application No. PCT/JP2023/021521 filed on Jun. 9, 2023, designating the United States of America, which is based on and claims priority to Japanese patent application JP 2022-075073, filed Apr. 28, 2022. The entire disclosures of the above-identified applications, including the specifications, the drawings, and the claims are incorporated herein by reference in their entirety.

### FIELD

Embodiments relate to a semiconductor device, and relates to a technique effectively applied to, for example, a semiconductor device including a complementary MOS (Metal Oxide Semiconductor) transistor (hereinafter referred to as CMOS transistor) that uses a semiconductor material with a larger bandgap than that of silicon.

### BACKGROUND

Japanese Patent Application Laid-open Publication No. 2009-89544 (Patent Document 1) describes a technique of putting a surge voltage within a withstand voltage of a switching power module by linking temperature change in a switching power module and a gate resistor that supplies an output of a gate drive circuit even when the temperature of the switching power module rises from, for example, 20 to 100 degrees Celsius due to heat generation.

Non-Patent Document 1 describes a technique of multi-chip mounting of a first semiconductor chip where a gate driver including a CMOS transistor using silicon carbide is formed, a second semiconductor chip where a power transistor using silicon carbide is formed, and a third semiconductor chip where a diode using silicon carbide is formed on one PCB interconnection substrate.

Non-Patent Document 2 describes a technique concerning a semiconductor device where a CMOS transistor using silicon and a power transistor using silicon carbide are monolithically integrated on a silicon carbide substrate.

### RELATED ART DOCUMENTS

### Patent Document

Patent Document 1: Japanese Patent Application Laid-open Publication No. 2009-89544

### Non-Patent Documents

Non-Patent Document 1: M. BarLow et. al, IEEE TRANSACTIONS ON POWER ELECTRONICS, VOL. 34, No. 11, November 2019
Non-Patent Document 2: M. Okamoto, A. Yao, H. Sato, and S. Harada, 2021 33rd International Symposium on Power Semiconductor Devices and ICs (ISPSD). IEEE, 2021, pp. 71-74.

Switching time of a power transistor used in powering a semiconductor device is changed by the temperature change. In this case, even if control parameters such as the switching time are adjusted to an optimal value at room temperature, the control parameters are deviated from the optimal value by the temperature change, and, as a result, there is a risk of the characteristic fluctuation and controllability deterioration of the power transistor. Also, for example, if the switching time is made shorter than the optimum value by the temperature rise, the voltage change rate or the current change rate is made larger, and therefore, there is a possibility of an unexpected failure due to surges or ringing. Also, for example, if the switching time is made longer than the optimum value by the temperature drop, the voltage change rate or the current change rate is made smaller, and therefore, there is a possibility of an unexpected failure due to increased switching loss. For this reason, a device for suppressing the change in the switching time due to the temperature change has been considered.

### SUMMARY

The semiconductor device in one embodiment includes a power transistor using a semiconductor material having a larger bandgap than that of silicon, and a switching circuitry for controlling switching of the power transistor. Here, the switching circuitry includes a CMOS transistor using a semiconductor material having a larger bandgap than that of silicon, and a resistance component electrically connected to the CMOS transistor. At this time, the change in the switching time of the power transistor caused by the temperature change is suppressed by the change in the resistance value of the resistance component caused by the temperature change. As used herein, the term “resistance component” is intended to refer to, e.g., a semiconductor device, a resistor device, a resistor component device, or a component having resistance or a resistance component (parasitic resistance) accompanying the wiring that is inherently not the resistor device, and is not intended to be regarded as, e. g., a resistance component inherently formed as the resistor device or a resistor component (device).

### Effects

According to one embodiment, the change in the switching time due to the temperature change can be suppressed.

### BRIEF DESCRIPTIONS OF THE DRAWINGS

FIG. 1 is a diagram showing an example of a circuit configuration using a silicon carbide power semiconductor device;

FIG. 2 is a diagram for explaining a Comparative Embodiment;

FIG. 3 is a diagram for explaining the basic idea of suppressing the temperature dependence of “turn-on time”;

FIG. 4 is a diagram for explaining the basic idea of suppressing the temperature dependence of “turn-off time”;

FIG. 5 is (a) an image showing an actual layout of a silicon carbide power semiconductor device, and (b) a diagram schematically showing a layout of a silicon carbide power semiconductor device;

FIG. 6 is a diagram showing a layout of a semiconductor chip on which a CMOS transistor that configures a switching circuitry is formed;

FIG. 7 is an enlarged view of a part of a region shown in FIG. 6 to be enlarged;

FIG. 8 is (a) a cross-sectional view taken along the line A-A in FIG. 7, and is (b) a cross-sectional view taken along the line B-B in FIG. 7;

FIG. 9 is a graph showing temperature dependence of “turn-on time”;

FIG. 10 is a diagram showing a device structure in a first modification example;

FIG. 11 is a diagram showing a device structure in a second modification example;

FIG. 12 is a diagram showing a device structure in a second typified aspect;

FIG. 13 is a diagram showing a layout of a semiconductor chip in a third typified aspect; and

FIG. 14 is a diagram collectively showing cross-sectional views each taken along the lines A-A, B-B, and C-C of FIG. 13;

### DETAILED DESCRIPTION

The same components are denoted by the same reference symbols in principle throughout all the drawings for describing the embodiments, and the repetitive description thereof will be omitted. Note that hatching may be used even in plan view so as to make the drawings easy to see.

### <Advantages of Wide Bandgap Semiconductor>

A power semiconductor device is required to have, for example, low on-resistance and low switching loss in addition to high withstand voltage. Here, the current mainstream of such a power semiconductor device is a field effect transistor formed on a semiconductor substrate mainly containing silicon. However, such a power semiconductor device is getting close to its theoretical performance limit.

In this regard, attention has been paid to a semiconductor device (hereinafter referred to as wide bandgap power semiconductor device) including a field effect transistor formed on a semiconductor substrate mainly containing a semiconductor material having a larger bandgap than that of silicon.

This is because a large bandgap means high dielectric breakdown strength, and therefore, this easily achieves a high withstand voltage.

If the semiconductor material itself has high dielectric breakdown strength, the withstand voltage can be ensured even if the drift layer that holds the withstand voltage is thin, and therefore, for example, the on-resistance of the power semiconductor device can be reduced by making the drift layer thin and increasing the impurity concentration.

That is, such a wide bandgap power semiconductor device is superior because of being capable of achieving both the improvement in the withstand voltage and the reduction in the on-resistance which are in a trade-off relationship with each other. Such a wide bandgap power semiconductor device with the advantages as described above also has an advantage of enabling high temperature operation and high-speed switching operation due to the large bandgap.

The technical idea in the present embodiment is a technical idea related to the wide bandgap power semiconductor device that uses the semiconductor material with the larger bandgap than that of silicon. A chemical compound typified by silicon carbide (SiC) and gallium nitride (GaN) can be exemplified as the semiconductor material with the larger bandgap than that of silicon. However, the technical idea in the present embodiment is not limited thereto, and is variously applicable to wide bandgap power semiconductor devices each using the semiconductor material with the larger bandgap than that of silicon.

Particularly, a wide bandgap power semiconductor device using silicon carbide will be described below as an example of the wide bandgap power semiconductor device.

The dielectric breakdown electric field strength of silicon carbide is about one order of magnitude larger than that of silicon. Therefore, the reduction in the on-resistance (element resistance) can be theoretically made to three or more orders of magnitude by thinning the drift layer for ensuring the withstand voltage to a thickness of about 1/10 and by increasing the impurity concentration to an impurity concentration of about 100 times. In addition, high temperature operation is also possible since its bandgap is about three times larger than the bandgap of silicon, and the wide bandgap power semiconductor device using silicon carbide (hereinafter referred to as silicon carbide power semiconductor device) has been awaited to provide a performance that exceeds that of the silicon power semiconductor device.

### <Circuit Configuration of Silicon Carbide Power Semiconductor Device>

First, an example of a circuit configuration of a silicon carbide power semiconductor device will be described below.

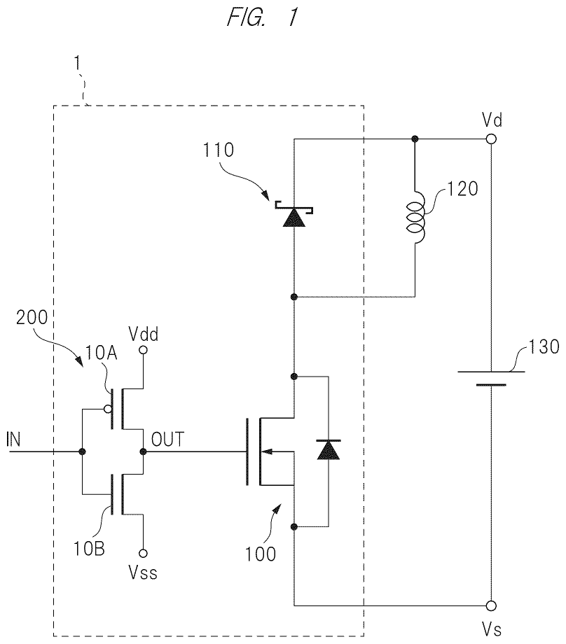

FIG. 1 shows the example of the circuit configuration using the silicon carbide power semiconductor device 1.

In FIG. 1, the silicon carbide power semiconductor device 1 has a power transistor 100, a Schottky barrier diode 110, and a switching circuitry 200. A power MOSFET (Metal Oxide Semiconductor Field Effect Transistor) and an IGBT (Insulated Gate Bipolar Transistor) can be exemplified as the power transistor 100. The power transistor 100, the Schottky barrier diode 110, and the switching circuitry 200 are formed while using silicon carbide. The silicon carbide power semiconductor device 1 is connected to a load 120 and an external power supply 130.

Specifically, an external power supply 130 is connected between a power supply potential Vd and a reference potential Vs, and the power transistor 100 and the Schottky barrier diode 110 are connected in series with the external power supply 130. In addition, a load 120 is connected in parallel with the Schottky barrier diode 110. The load 120 is, for example, a motor and includes an inductance.

A switching circuitry 200 is connected to the gate of the power transistor 100, and the switching of the power transistor is controlled by the switching circuitry 200. The switching circuitry 200 includes a CMOS transistor, and this CMOS transistor is made of a p-channel field effect transistor 10A and an n-channel field effect transistor 10B that are connected in series between a power supply potential Vdd and a reference potential Vₛₛ. In the following description, a p-channel field effect transistor will be abbreviated as pFET, and an n-channel field effect transistor will be abbreviated as nFET. At this time, the gate of the pFET 10A is electrically connected to the gate of the nFET 10B.

Here, the inputs of the switching circuitry 200 are the gate of the pFET 10A and the gate of the nFET 10B electrically connected to each other. In contrast, the output of the switching circuitry 200 is the connection node between the drain of the pFET 10A and the drain of the nFET 10B, and this connection node is electrically connected to the gate of the power transistor 100. In the circuit configured as described above, the switching of the power transistor 100 is controlled based on the control signal input to the input of the switching circuitry 200, thereby controlling the current flowing through the load 120.

The operation of controlling the switching of the power transistor 100 by the switching circuitry 200 will then be described. In FIG. 1, it is assumed that a low level signal (for example, Vss) is input to the input of the switching circuitry 200. In this case, “Vss” is applied to the gate of the pFET 10A, which configures the switching circuitry 200, and the gate of the nFET 10B, which configures the switching circuitry 200. As a result, the pFET 10A is turned on while the nFET 10B is turned off. Accordingly, a high level signal (for example, Vdd) is output from the output of the switching circuitry 200.

Specifically, when the pFET 10A is turned on, a current flows in a path of “the power supply potential Vdd-source of the pFET 10A→drain of the pFET 10A→output of the switching circuitry 200→gate of the power transistor 100”. By this current, charges are accumulated in the gate-drain capacitance of the power transistor 100. As a result, finally, the gate voltage of the power transistor becomes “Vdd”, and the power transistor is turned on. Thereby, a current can flow through the load 120 to drive the load.

In contrast, in FIG. 1, it is assumed that a high level signal (for example, Vdd) is input to the input of the switching circuitry 200. In this case, “Vdd” is applied to the gate of the pFET 10A, which configures the switching circuitry 200, and to the gate of the nFET 10B, which configures the switching circuitry 200. As a result, the pFET 10A is turned off while the nFET 10B is turned on. Because of this, a low level signal (for example, Vss) is output from the output of the switching circuitry 200. As a result, when the nFET 10B turns on, the charges accumulated in the gate-drain capacitance of the power transistor 100 are discharged, and a current flows through a path of “the gate of the power transistor 100→output of the switching circuitry 200→drain of the nFET 10B→source of the nFET 10B→reference potential Vss”. As a result, finally, the gate voltage of the power transistor 100 becomes “Vss”, and the power transistor 100 is turned off. Because of this, the current flowing through the load 120 is cut off. At this time, since the load 120 includes the inductance, by the cutting off of the current flowing through the load 120, back-electromotive force attempting to keep the current flowing is generated in the inductance. The current based on this back-electromotive force flows through the Schottky barrier diode 110. That is, a reflux (freewheeling diode) current flows through a closed loop made of the load 120 and the Schottky barrier diode 110.

As described above, since the switching operation of the power transistor 100 is controlled by the switching circuitry 200, the load 120 can be driven.

### Comparative Embodiment

Next, a Comparative Embodiment will be described.

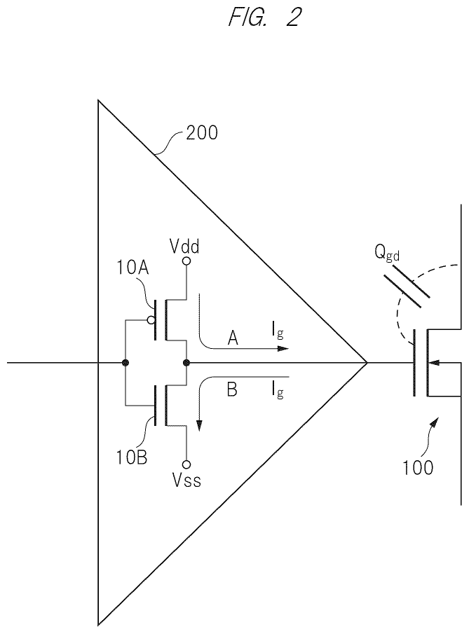

FIG. 2 is a diagram for explaining a Comparative Embodiment.

In FIG. 2, from previous studies, it is known that the switching time can be approximated by the following (Equation 1).

$${t}_{s w} ≅ 0.8 \times {Q}_{g d} / {I}_{g} \qquad ( Equation 1 )$$

t_{sw}: Switching time
Q_{gd}: Amount of the charges accumulated in the gate-drain capacitance of the power transistor
I_{g}: Gate current

Here, during the “turn-on time”, the gate current I_{g} is equivalent to the drain current of the pFET 10A flowing in the path “A”. In contrast, during the “turn-off time”, the gate current I_{g} is equivalent to the drain current of the nFET 10B flowing in the path “B”.

In this specification, the term “switching time” is used as a concept that includes both “turn-on time” during which a state of the power transistor changes from an off state to an on state and “turn-off time” during which the state of the power transistor changes from the on state to the off state.

When the drain-source voltage (Vas) at turning off of the power transistor is assumed to 100%, the “turn-on time” is defined as the time taken for change from the drain-source voltage of 90% to the drain-source voltage of 10%. For example, if the drain-source voltage (Vas) at turning off is 600 V, the time taken for change from 540 V to 60 V is defined as the “turn-on time”.

When the drain-source voltage (Vas) at turning off of the power transistor is 100%, the term “turn-off time” is defined as the time taken for change from the drain-source voltage of 10% to the drain-source voltage of 908. For example, if the drain-source voltage (Vas) at turning off is 600 V, the time taken for change from 60 V to 540 V is defined as the “turn-off time”.

Here, in the pFET 10A and nFET 10B which configure the switching circuitry 200, the drain current during conduction is changed by the temperature change. In this regard, in consideration of the Equation 1 above, the change in the drain current (gate current I_{g} of the power transistor 100) of the pFET 10A or nFET 10B by the temperature change means that the switching time t_{sw} of the power transistor 100 is changed by the temperature change. Here, from the viewpoint of suppressing the characteristic fluctuation and controllability deterioration of the power transistor due to temperature change, the switching time t_{sw} of the power transistor 100 is desirably constant even under the temperature change. From this, it is found that the circuit configuration of the switching circuitry 200 shown in FIG. 2 has a room to be improved from the viewpoint of making the switching time t_{sw} of the power transistor 100 constant even under the temperature change.

Thus, the present embodiment adopts a devisal for overcoming the above-described room to be improved. The technical idea in the present embodiment with the devisal will be described below.

### Basic Idea in Embodiment

The basic idea in the present embodiment is, for example, an idea in which the temperature dependence of the drain current of the CMOS transistor that configures the switching circuitry is compensated by the temperature dependence of the resistance component included in the switching circuitry. In other words, the basic idea can also be interpreted as the basic idea in which the switching circuitry includes a resistance component having the opposite characteristics to the temperature dependence of the gate current of the power transistor that is switching-controlled by the switching circuitry to use the change in the resistance component described above due to the temperature change for suppressing the change in the gate current due to the temperature change.

According to such a basic idea, the change in the gate current can be compensated by the change in the resistance component, and therefore, the temperature dependence of the gate current can be reduced. This means the temperature dependence of switching time can be reduced in consideration of the Equation 1 described above. Therefore, according to the basic idea, the temperature dependence of switching time can be reduced, and therefore, the performance of the silicon carbide power semiconductor device can be improved.

### <<Basic Idea for “Turn-On Time”>>

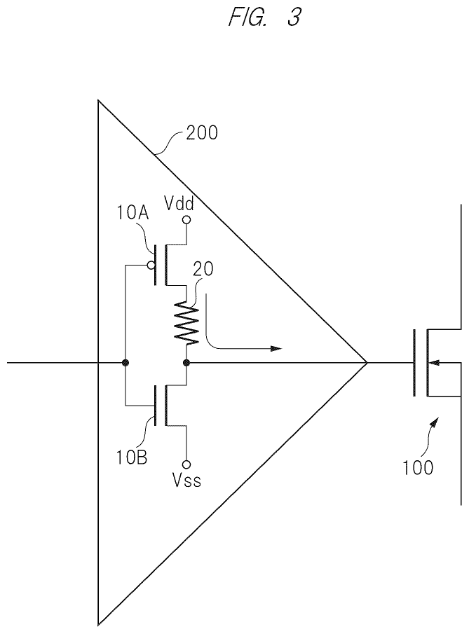

FIG. 3 is a diagram for explaining the basic idea of suppressing the temperature dependence of “turn-on time”.

In FIG. 3, during the “turn-on time”, the drain current flowing through the pFET 10A corresponds to the gate current flowing into the gate of the power transistor 100. Since the drain current flowing through the pFET 10A is changed by the temperature change, the gate current is changed by the temperature change.

Particularly, the drain current flowing through the pFET 10A is treated to be increased by the temperature rise. In this case, the gate current flowing into the gate of the power transistor 100 is increased by the temperature rise.

In this regard, in FIG. 3, the basic idea is the idea in which a resistance component 20 included in the switching circuitry 200 is provided between the drain of the pFET 10A which configures the switching circuitry 200 and the gate of the power transistor 100. Particularly, this resistance component 20 is made of a resistance component having the opposite characteristics to the temperature dependence of the drain current of the pFET 10A. For this reason, the change in the drain current of the pFET 10A is suppressed by the change in the resistance component 20. For example, since the drain current of the pFET 10A is increased by the temperature rise, the resistance component 20 is made of a resistance component having characteristics, the resistance value of which is increased by the temperature rise. As a result, the increase in the drain current of the pFET 10A is suppressed by the increase in the resistance value of the resistance component 20.

Specifically, an equation is used for explanation.

The gate current being expressed by (Equation 2) has been considered.

$${I}_{g} = ( {V}_{d d} - {V}_{g} ( T ) ) / ( Rpf ( T ) + Rpw ( T ) ) \qquad ( Equation 2 )$$

I_{g}: Gate current
V_{dd}: Power supply potential of switching circuitry
V_{g}(T): Gate voltage (=Miller plateau voltage)
Rpf(T): Equivalent resistance excluding the interconnection resistance of pFET 10A
Rpw(T): Resistance component (interconnection resistance)
T: Temperature

Here, the Equation 2 is an expression for the gate current I_{g} of the power transistor 100 during the “turn-on time”, and this gate current I_{g} can also be rephrased as the drain current of the pFET 10A.

V_{g}(T) is the Miller plateau voltage, and its value is decreased by the temperature rise. Here, the Miller plateau voltage V_{g}(T) is the gate voltage value at which charging and discharging of the Miller capacitance begins at switching. The Miller plateau voltage V_{g}(T) is decreased by the temperature rise mainly due to the decrease in the threshold voltage of the power transistor 100 due to the temperature rise.

Rpf(T) means equivalent resistance excluding the interconnection resistance of the pFET 10A, is typically channel resistance, and its value is decreased by the temperature rise. That is, the characteristics in which the drain current of the pFET 10A increases in response to the temperature rise are exhibited.

Rpw(T) is typically the interconnection resistance of the pFET 10A, but may also be a resistor connected to the drain end and/or the source end of the pFET 10A. Rpw(T) corresponds to the resistance component 20 in FIG. 3.

In Equation 1, Q_{gd} is hardly changed by the temperature. Therefore, if the fluctuation of the gate current I_{g} with respect to temperature change can be suppressed, the temperature fluctuation of “turn-on time” can be suppressed. Equation 2 shows relationship in which decrease of values of Rpf(T) and V_{g}(T) increases I_{g} while increase of a value of Rpw(T) decreases I_{g} Since Rpf(T) and V_{g}(T) are decreased by rise of the temperature T, it is found that, in order to cancel the fluctuation of the gate current I_{g} in Equation 2, it is enough to increase Rpw(T) so as to compensate for the fluctuation of I_{g} at the rise of the temperature T.

From the above, the basic idea for “turn-on time” is the basic idea in which, if the temperature dependence of the resistance component Rpw(T) (resistance component 20) of the switching circuitry 200 is the temperature dependence showing that the resistance value is increased by the temperature rise, the change in the gate current I_{g} of the power transistor 100 due to the temperature rise can be decreased. In this case, the change in the “turn-on time” due to the temperature change can be reduced based on Equation 1.

Note that FIG. 3 describes the example of providing the resistance component 20 on the drain side of the pFET 10A. However, the basic idea for “turn-on time” is not limited thereto, and, for example, the resistance component 20 may be provided on the source side of the pFET 10A, or both on the drain side and on the source side.

### <<Basic Idea for “Turn-Off Time”>>

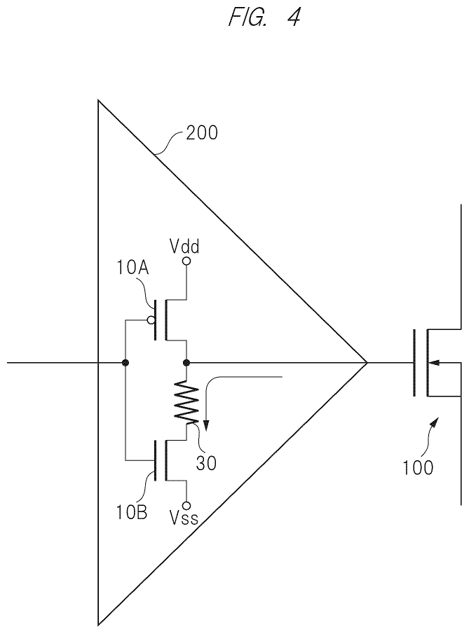

FIG. 4 is a diagram for explaining the basic idea of suppressing the temperature dependence of “turn-off time”.

In FIG. 4, during the “turn-off time”, the drain current flowing through the nFET 10B corresponds to the gate current flowing out of the gate of the power transistor 100. Since the drain current flowing through the nFET 10B is changed by the temperature change, the gate current is changed by the temperature change. Particularly, the drain current flowing through the nFET 10B is treated to be increased by the temperature rise. In this case, the gate current of the power transistor 100 is increased by the temperature rise.

In this regard, in FIG. 4, the basic idea is the idea in which a resistance component 30 included in the switching circuitry 200 is provided between the drain of the nFET 10B which configures the switching circuitry 200 and the gate of the power transistor 100. Particularly, this resistance component 30 is made of a resistance component having the opposite characteristics to the temperature dependence of the drain current of the nFET 10B. For this reason, the change in the drain current of the nFET 10B is suppressed by the change in the resistance component 30. For example, since the drain current of the nFET 10B is increased by the temperature rise, the resistance component 30 is made of a resistance component having characteristics, the resistance value of which is increased by the temperature rise. As a result, the increase in the drain current of the nFET 10B is suppressed by the increase in the resistance value of the resistance component 30.

However, more specifically, the basic idea needs to be divided by cases, and therefore, an equation is used for this point.

The gate current being expressed by (Equation 3) has been considered.

$${I}_{g} = ( {V}_{g} ( T ) - {V}_{s s} ) / ( Rnf ( T ) + Rnw ( T ) ) \qquad ( Equation 3 )$$

I_{g}: Gate current
Vₛₛ: Reference potential of switching circuitry
V_{g}(T): Gate voltage (=Miller plateau voltage)
Rnf(T): Equivalent resistance excluding the interconnection resistance of nFET 10B
Rnw(T): Resistance component (interconnection resistance)
T: Temperature

V_{g}(T) is the Miller plateau voltage, and its value is decreased by the temperature rise.

Rnf(T) means equivalent resistance excluding the interconnection resistance of the nFET 10B, is typically channel resistance, and its value is decreased by the temperature rise. That is, the characteristics in which the drain current of the nFET 10B increases in response to the temperature rise are exhibited.

Rnw(T) is typically the interconnection resistance of the nFET 10B, but may also be a resistor connected to the drain end and/or the source end of the nFET 10B. Rnw(T) corresponds to the resistance component 30 in FIG. 4.

In Equation 1, Q_{gd} is hardly changed by the temperature. Therefore, if the fluctuation of the gate current I_{g} in response to the temperature change can be suppressed, the temperature fluctuation of “turn-off time” can be suppressed. Equation 3 shows relationship in which decrease of a value of Rnf(T) increases I_{g} while increase of a value of Rnw(T) decreases I_{g}. Also, Equation 3 shows relationship in which increase of a value of V_{g}(T) increases I_{g}, this relationship is opposite to the relationship of Equation 2. Increase of the temperature T decreases Rnf(T) and increases I_{g}, but decreases V_{g}(T), and thus, decreases I_{g}. Both inversely act on I_{g}. Therefore, the following three cases are considerable.

Case (1): The increase in I_{g} based on Rnf(T) due to the temperature rise is larger than the decrease in I_{g} based on V_{g}(T). In this case, according to Equation 3, Rnw(T) is increased while I_{g} is decreased so as to cancel the increase in I_{g} that could not be canceled by the relationship between Rnf(T) and V_{g}(T).

Case (2): The increase in I_{g} based on Rnf(T) due to the temperature rise is smaller than the decrease in I_{g} based on V_{g}(T). In this case, according to Equation 3, Rnw(T) is decreased while I_{g} is increased so as to cancel the decrease in I_{g} caused by the relationship between Rnf(T) and V_{g}(T).

Case (3): The increase in I_{g} based on Rnf(T) due to the temperature rise is equal to the decrease in I_{g} based on V_{g}(T). In this case, according to Equation 3, Rnw(T) is not changed by the temperature.

From the above, the basic idea for “turn-off time” needs to be classified into a case where the temperature dependence of the drain current flowing through the nFET 10B has a larger influence than the temperature dependence of the gate voltage V_{g} of the power transistor 100 and a case where the temperature dependence of the gate voltage V_{g} of the power transistor 100 has a larger influence than the temperature dependence of the drain current flowing through the nFET 10B.

Then, in the case where the temperature dependence of the drain current flowing through the nFET 10B has a larger influence than the temperature dependence of the gate voltage V_{g} of the power transistor 100, the basic idea for “turn-off time” is the basic idea in which the change in the gate current I_{g} due to the temperature rise can be decreased if the temperature dependence of the resistance component Rnw(T) (resistance component 30) of the switching circuitry 200 is the temperature dependence in which the resistance value is increased by the temperature rise. In this case, according to Equation 1, the change in the “turn-off time” due to the temperature change can be decreased.

In contrast, in the case where the temperature dependence of the gate voltage V_{g} of the power transistor 100 has a larger influence than the temperature dependence of the drain current flowing through the nFET 10B, the basic idea for “turn-off time” is the basic idea in which the change in the gate current I_{g} due to the temperature rise can be decreased if the temperature dependence of the resistance component Rnw(T) (resistance component 30) of the switching circuitry 200 is the temperature dependence in which the resistance value is decreased by the temperature rise. In this case, according to Equation 1, the change in the “turn-off time” due to the temperature change can be decreased.

Note that FIG. 4 shows the example of providing the resistance component 30 on the drain side of the nFET 10B. However, the basic idea for “turn-off time” is not limited thereto. For example, the resistance component 30 may be provided on the source side of the nFET 10B or both on the drain side and the source side.

Typified aspects typifying the basic ideas described above will be described below.

### <First Typified Aspect>

### <<Layout of Silicon Carbide Power Semiconductor Device>>

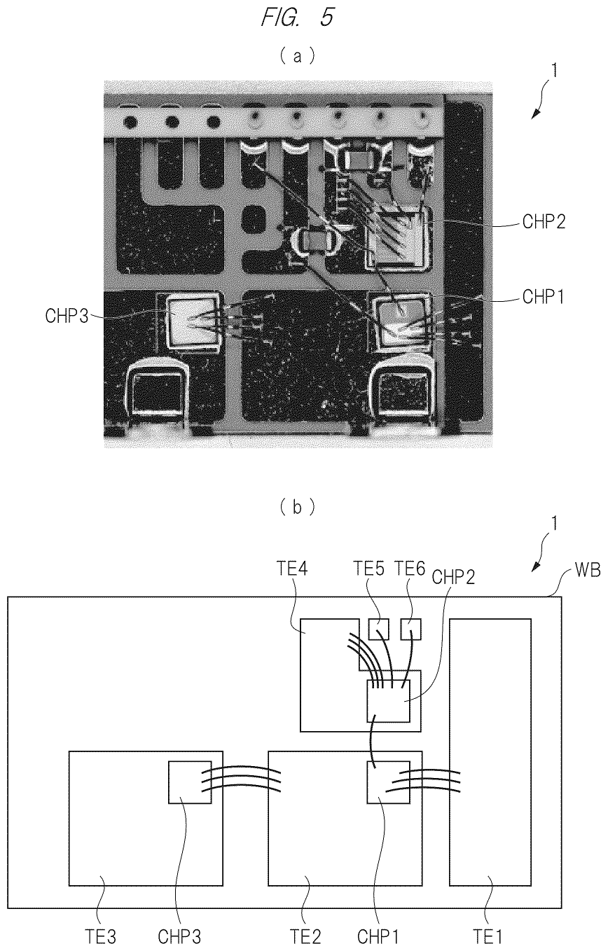

FIG. 5 is a diagram showing the layout of the silicon carbide power semiconductor device 1. Particularly, part (a) of FIG. 5 is an image showing an example of the actual layout of the silicon carbide power semiconductor device 1, and part (b) FIG. 5 is a diagram schematically showing the layout of the silicon carbide power semiconductor device 1.

In part (b) of FIG. 5, the silicon carbide power semiconductor device 1 has a wiring substrate WB. Terminals TE1 to TE6, which serve as conductor regions, are formed on the wiring substrate WB. Although not particularly limited, the wiring substrate WB may adopt a base substrate made of, for example, a SiN-AMC (silicon nitride-active metal copper circuit) substrate and a Cu—Mo—Cu (CMC) composite material bonded to the lower surface thereof in order to improve heat dissipation or match thermal expansion coefficient with the semiconductor chip.

When the silicon carbide power semiconductor device 1 is viewed as a whole, the terminal TE6 is the signal input node (IN in FIG. 1), and the terminal TE2 is the output node (drain of the power transistor). The other terminals TE1 and TE3 to TE5 are power supply nodes.

The reference potential Vs shown in FIG. 1 is applied to the terminal TE1, and the power supply potential Vd shown in FIG. 1 is applied to the terminal TE3. Also, the reference potential Vₛₛ shown in FIG. 1 is applied to the terminal TE4, and the power supply potential V_{dd} shown in FIG. 1 is applied to the terminal TE5.

A semiconductor chip CHP1 where the power transistor is formed is mounted on the terminal TE2, and a semiconductor chip CHP3 where the Schottky barrier diode is formed is mounted on the terminal TE3. Also, a semiconductor chip CHP2 where the CMOS transistor configuring the switching circuitry is formed is mounted on the terminal TE4.

Then, the terminal TEL is connected by a wire to the source of the power transistor formed in the semiconductor chip CHP1. Also, the terminal TE2 is connected by a wire to the anode of the Schottky barrier diode formed on the semiconductor chip CHP3.

The terminal TE4 is connected by a wire to the source of the nFET configuring a CMOS transistor formed on the semiconductor chip CHP2. Also, the terminal TE5 is connected by a wire to the source of the pFET configuring a CMOS transistor. Furthermore, the terminal TE6 is connected by a wire to the gate of the pFET and the gate of the nFET which are electrically connected to each other. That is, the terminal TE6 is connected by a wire to the input of the CMOS transistor configuring the switching circuitry. In contrast, the semiconductor chip CHP1 is connected by a wire to the semiconductor chip CHP2. Specifically, the gate of the power transistor formed on the semiconductor chip CHP1 is connected by a wire to the output of the CMOS transistor formed on the semiconductor chip CHP2.

In the silicon carbide power semiconductor device 1 laid out as described above, the semiconductor chip CHP1 and the semiconductor chip CHP2 are close to each other. This means that the output of the CMOS transistor formed on the semiconductor chip CHP2 and the gate of the power transistor formed on the semiconductor chip CHP1 are connected to each other by a short-length wire. As a result, the parasitic inductance of the wire can be reduced, and therefore, high-speed switching operation can be achieved. For example, the silicon carbide power semiconductor device 1 with the layout shown in FIG. 5 can achieve a switching time of several nanoseconds. In other words, “turn-on time” and “turn-off time” of several nanoseconds or less can be achieved.

In addition, the power transistor chip (semiconductor chip CHP1) and the CMOS transistor chip (semiconductor chip CHP2) are arranged close to each other on a wiring substrate WB with high thermal conductivity as described above. For this reason, the heat generated by the power transistor chip is in cooperation with the temperature of the CMOS transistor chip. In order to strengthen thermal coupling between the chips as described above, experimental has been specifically made under a condition in which a minimum distance between the two chips is 0.8 mm, but a condition in which this is in the range of about 0 to 5 mm is desirable.

### <<Layout of Semiconductor Chip>>

Next, the layout of the semiconductor chip CHP2 where the CMOS transistor configuring the switching circuitry is formed will be described.

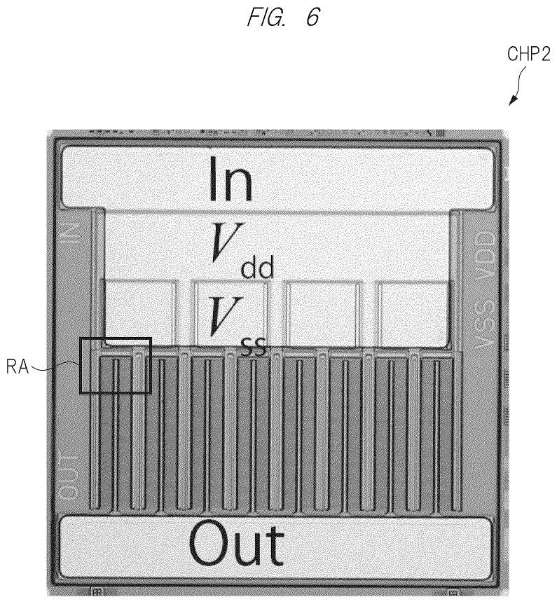

FIG. 6 is a diagram showing the layout of the semiconductor chip CHP2 on which the CMOS transistor configuring the switching circuitry is formed. In FIG. 6, a plurality of pads are formed on the surface of the semiconductor chip CHP2. Specifically, an input pad (In) of the CMOS transistor, a power supply potential pad (V_{dd}), a reference potential pad (Vₛₛ), and an output pad (Out) of the CMOS transistor are formed on the semiconductor chip CHP2.

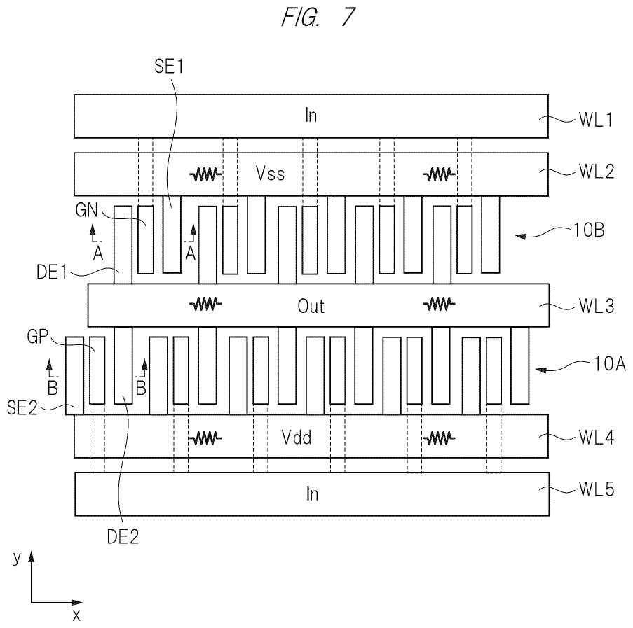

FIG. 7 is an enlarged view where the region RA in FIG. 6 is illustrated to be enlarged. As shown in FIG. 7, metal wirings WL1 to WL5 are arranged side by side in the y direction, and each of the metal wirings WL1 to WL5 extends in the x direction. Each of these metal wirings WL1 to WL5 is made of, for example, an aluminum wiring containing aluminum as a main component.

Here, the term “main component” refers to the component contained most and is used to indicate that containing of other components is not excluded. For example, the phrase “containing aluminum as the main component” implies that aluminum is contained most.

The metal wiring WL1 is an input wiring (In) of the CMOS transistor, and the metal wiring WL2 is a reference wiring to which the reference potential (Vₛₛ) is applied. Also, the metal wiring WL3 is an output wiring (Out) of the CMOS transistor, and the metal wiring WL4 is a power supply wiring to which the power supply potential (V_{dd}) is applied. Furthermore, the metal wiring WL5 is an input wiring (In) of the CMOS transistor. In the metal wirings WL1 to WL5 configured as described above, a plurality of nFETs 10B that configures the CMOS transistor are formed between the metal wirings WL2 and WL3, and the plurality of nFETs 10B are arranged side by side in the x direction. Each of the plurality of nFETs 10B has a source electrode SE1 and a drain electrode DE1 and also has a gate electrode GN arranged between the source electrode SE1 and the drain electrode DE1. Here, the source electrode SE1 is electrically connected to the metal wiring WL2, while the drain electrode DE1 is electrically connected to the metal wiring WL3. The gate electrode GN is electrically connected to the metal wiring WL1.

Meanwhile, a plurality of pFETs 10A that configure the CMOS transistors are formed between the metal wiring WL3 and the metal wiring WL4, and the plurality of pFETs 10A are arranged side by side in the x direction. Each of the plurality of pFETs 10A has a source electrode SE2 and a drain electrode DE2 and also has a gate electrode GP arranged between the source electrode SE2 and the drain electrode DE2. Here, the source electrode SE2 is electrically connected to the metal wiring WL4, while the drain electrode DE2 is electrically connected to the metal wiring WL3. The gate electrode GP is electrically connected to the metal wiring WL5.

Each of the source electrode SE, the source electrode SE2, the drain electrode DE1, the drain electrode DE2, the metal wiring WL2, the metal wiring WL3, and the metal wiring WL4 is made of an aluminum wiring in the same layer, and is patterned by a photolithography technique.

The layout of the semiconductor chip CHP2 is configured as described above.

### <<Device Structure of CMOS Transistor>>

Subsequently, the device structure of the nFET configuring the CMOS transistor will be described, and then, the device structure of the pFET configuring the CMOS transistor will be described.

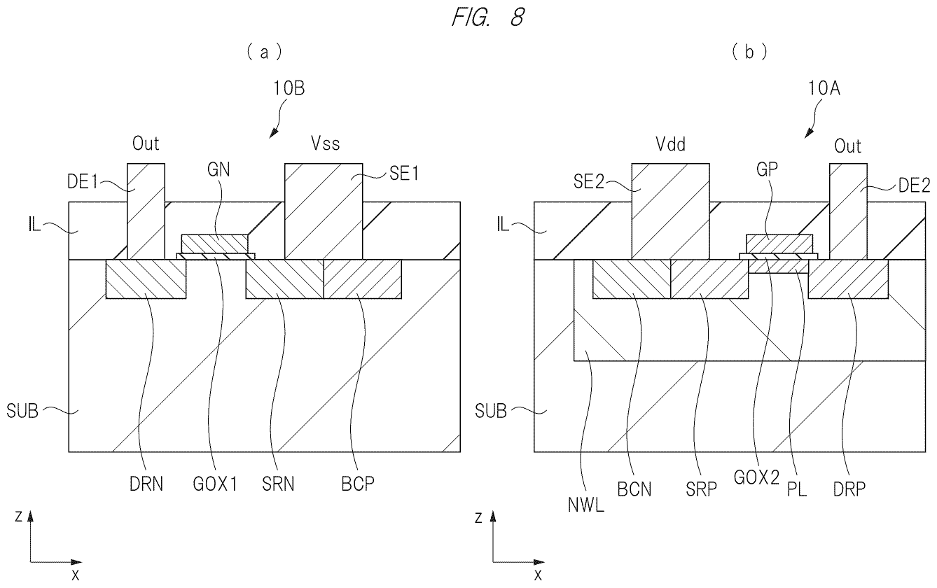

Part (a) of FIG. 8 is a cross-sectional view taken along the line A-A in FIG. 7, and is a diagram showing the device structure of the nFET 10B configuring the CMOS transistor.

In part (a) of FIG. 8, for example, a drain region DRN made of an n-type diffusion layer and a source region SRN made of an n-type diffusion layer are formed to separate from each other in a p-type silicon carbide substrate SUB. Also, a p-type body contact region BCP is formed in contact with the source region SRN. Meanwhile, a region sandwiched between the source region SRN and the drain region DRN is a channel forming region, and a gate insulating film GOX1 is formed on the channel forming region. And a gate electrode GN is formed on the gate insulating film GOX1.

Next, an insulating layer IL is formed on the surface of the p-type silicon carbide substrate SUB covering the gate electrode GN, and the drain electrode DE1 and the source electrode SE1 are formed so as to penetrate this insulating layer IL. The drain electrode DE1 is formed so as to penetrate the insulating layer IL to reach the drain region DRN and is electrically connected to the drain region DRN. In contrast, the source electrode SE1 is formed so as to penetrate the insulating layer IL to reach both the source region SRN and the p-type body contact region BCP, and is electrically connected to the source region SRN and the p-type body contact region BCP.

Next, the drain electrode DE1 is electrically connected to the metal wiring WL3 in a planar direction not illustrated (see FIG. 7). In contrast, the source electrode SE1 is electrically connected to the metal wiring WL2 in a planar direction not illustrated (see FIG. 7).

The nFET 10B is configured as described above.

Next, part (b) of FIG. 8 is a cross-sectional view taken along the line B-B of FIG. 7, and is a diagram showing the device structure of the pFET 10A configuring the CMOS transistor.

In part (b) of FIG. 8, for example, an n-type well NWL is formed in the p-type silicon carbide substrate SUB, and a drain region DRP made of a p-type diffusion layer and a source region SRP made of a p-type diffusion layer are formed to separate from each other in the n-type well NWL. Also, an n-type body contact region BCN is formed in contact with the source region SRP. In contrast, a depleted p-type buried region PL is formed in a region sandwiched between the source region SRP and the drain region DRP, and a gate insulating film GOX2 is formed on the p-type buried region PL. And, a gate electrode GP is formed on the gate insulating film GOX2.

Next, the insulating layer IL is formed on the surface of the p-type silicon carbide substrate SUB covering the gate electrode GP, and the drain electrode DE2 and the source electrode SE2 are formed so as to penetrate the insulating layer IL. The drain electrode DE2 is formed so as to penetrate the insulating layer IL to reach the drain region DRP and is electrically connected to the drain region DRP. In contrast, the source electrode SE2 is formed so as to penetrate the insulating layer IL to reach both the source region SRP and the n-type body contact region BCN, and is electrically connected to the source region SRP and the n-type body contact region BCN.

Next, the drain electrode DE2 is electrically connected to the metal wiring WL3 in a planar direction not illustrated (see FIG. 7). In contrast, the source electrode SE2 is electrically connected to the metal wiring WL4 in a planar direction not illustrated (see FIG. 7).

The pFET 10A is configured as described above.

Here, in the pFET 10A, a depleted p-type buried region PL is formed in the channel forming region. As a result, the pFET 10A adopts a so-called “buried channel structure” in which a channel is formed in the lower layer of the p-type buried region PL. The reason for this is as follows.

It is known that a field effect transistor formed on a silicon carbide substrate has a high density of an interface state at the MOS interface, to cause the low channel mobility and the high on-resistance. The interface state is generated by, for example, a heat treatment process when forming a gate insulating film, and becomes apparent particularly because of causing a large threshold voltage of a pFET.

In this regard, according to the results of the examination, a donor-like trap (hole trap) exists near the center of the bandgap, and a positive hole (hole) that is trapped once is not detrapped by thermal energy due to the large bandgap of silicon carbide. The trapped hole behaves as an effective positive fixed charge, and therefore, the threshold voltage of the pFET 10A is negatively shifted. That is, the threshold voltage of the pFET 10A is increased. Here, the nFET 10B also includes this hole trap, and an effective positive fixed charge is generated by application of negative gate bias. However, when an inversion layer is induced in the channel by application of positive gate bias, the electrons configuring the inversion layer and the holes in the hole trap recombine with each other, and return to electrically neutral, and do not affect the electrical characteristics. Thus, although the nFET 10B is less susceptible to the influence of the hole trap, the influence becomes apparent in the pFET 10A.

Therefore, the pFET 10A adopts not a “surface channel structure” but the “buried channel structure” in order to avoid the influence of the interface state.

Here, it is conceivable to use an ion implantation method to form the “buried channel structure”. However, when p-type impurities such as aluminum are ion-implanted into a silicon carbide substrate, an implantation defect occurs to cause and a side effect of reduced channel mobility. For this reason, in the first typified aspect, the “buried channel structure” is formed in an epitaxial layer. As a result, the impurities are not implanted by ion implantation, and therefore, the on-resistance of the pFET 10A can be reduced, and the threshold voltage can be reduced.

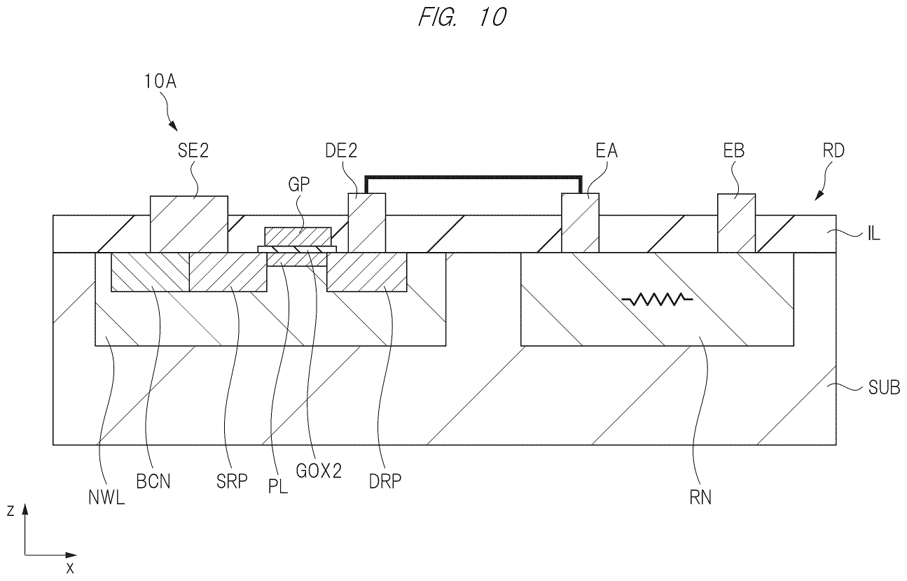

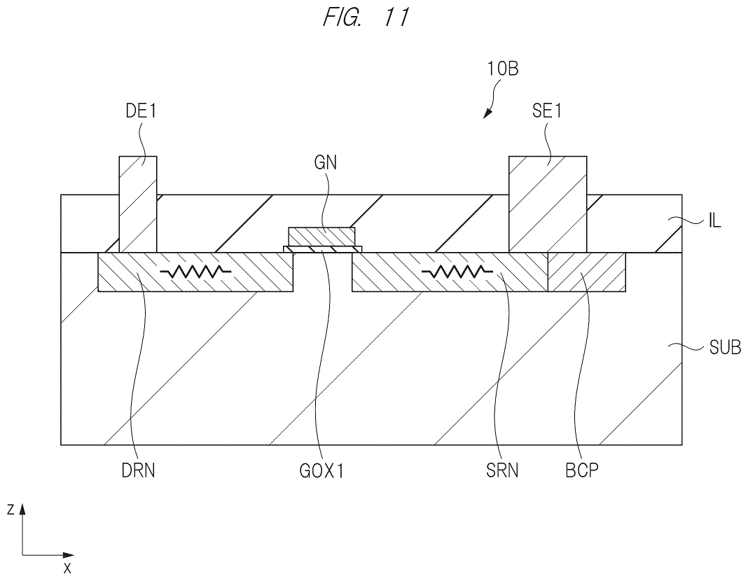

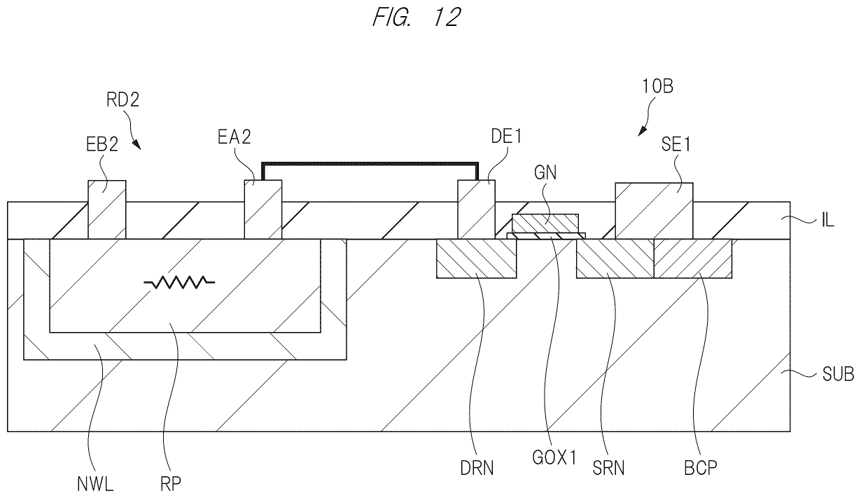

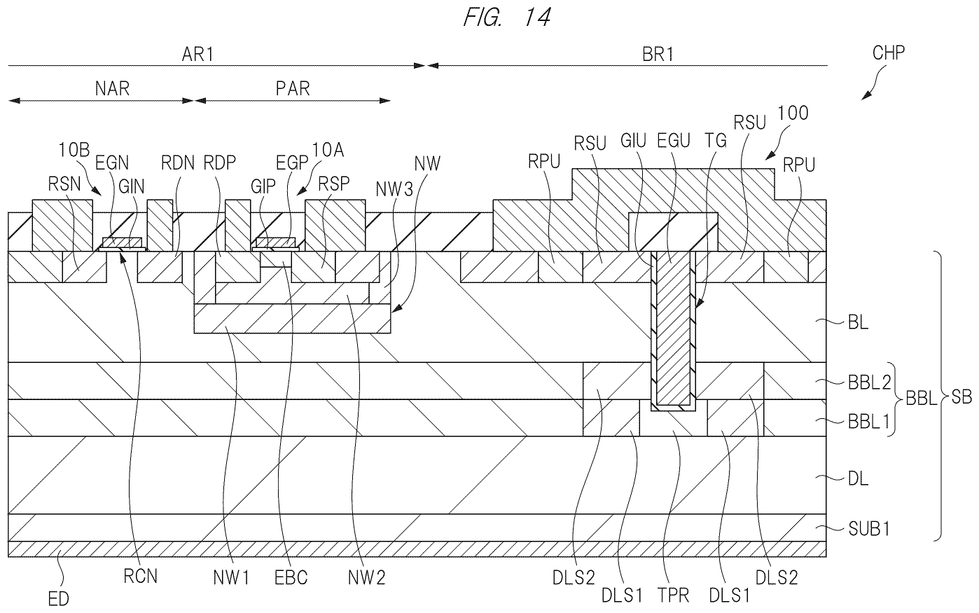

Note that FIG. 8 shows the structure where the pFET 10A and the nFET 10B are formed on the p-type silicon carbide substrate SUB. However, if the p-type silicon carbide substrate SUB is difficult to be used, a similar structure can be formed by epitaxially growing the p-type silicon carbide layer on an n-type silicon carbide substrate or a semi-insulating silicon carbide substrate. A structure of a CMOS region AR1 described later in FIG. 14 can also be used as it is. For the substitution of the p-type silicon carbide substrate SUB, the same is true in FIG. 10, FIG. 11 and FIG. 12 described later.

### <<Features in First Typified Aspect>>

Next, the feature points in the first typified aspect will be described.

The basic idea is the idea in which the change in the switching time of the power transistor due to the temperature change is suppressed by the change in the resistance value due to the temperature change in the resistance component electrically connected to the CMOS transistor. Here, the feature point in the first typified aspect is to, for example, use metal wirings WL2 to WL4 as the resistance components electrically connected to the CMOS transistor as shown in FIG. 7. Specifically, the feature point in the first typified aspect is to achieve the use of the interconnection resistance of the metal wirings WL2 to WL4 as the resistance components described above by intentionally extending the metal wirings WL2 to WL4 in the x direction.

For example, in focusing on “turn-on time” of the switching time, the change in the “turn-on time” due to the temperature rise can be decreased if the temperature dependence of the resistance component Rpw(T) of the switching circuitry is the temperature dependence in which the resistance value is increased by the temperature rise. Particularly, the change in the “turn-on time” can be suppressed by using a resistance component having the temperature dependence in which the resistance value is increased by the temperature rise, as the resistance component electrically connected to the pFET 10A.

In this regard, in the first typified aspect, for example, as shown in FIG. 7, the interconnection resistance of the metal wiring WL3 electrically connected to the drain electrode DE2 of the pFET 10A and the metal wiring WL4 electrically connected to the source electrode SE2 of the pFET 10A are used as the resistance component electrically connected to the pFET 10A. Here, each of the metal wiring WL3 and the metal wiring WL4 is made of the wiring containing aluminum as the main component, and has the characteristics in which the resistance value is increased by the temperature rise. Therefore, according to the first typified aspect, the change in the “turn-on time” is suppressed by the change in the interconnection resistance of the metal wiring WL3 and the change in the interconnection resistance of the metal wiring WL4, and, as a result, the “turn-on time” can be kept almost constant regardless of the temperature rise.

In contrast, in focusing on “turn-off time” of the switching time, the change in the “turn-off time” due to the temperature rise depends on conditions. That is, it is necessary to divide the conditions into a case where the temperature dependence of the drain current flowing through the nFET 10B has a larger influence than the temperature dependence of the gate voltage V_{g} of the power transistor 100 and a case where the temperature dependence of the gate voltage V_{g} of the power transistor 100 has a larger influence than the temperature dependence of the drain current flowing through the nFET 10B.

Then, in focusing on the case where the temperature dependence of the drain current flowing through the nFET 10B has a larger influence than the temperature dependence of the gate voltage V_{g} of the power transistor 100, the change in “turn-off time” can be decreased if the temperature dependence of the resistance component Rnw(T) of the switching circuitry is temperature dependence in which the resistance value is increased by the temperature rise. The change in the “turn-off time” can be suppressed particularly when the resistance component having the characteristics in which the resistance value is increased by the temperature rise is used as the resistance component electrically connected to the nFET 10B.

In this regard, in the first typified aspect, for example, as shown in FIG. 7, the interconnection resistance of the metal wiring WL3 electrically connected to the drain electrode DE1 of the nFET 10B and the metal wiring WL2 electrically connected to the source electrode SE1 of the nFET 10B are used as the resistance component electrically connected to the nFET 10B. Here, each of the metal wiring WL2 and the metal wiring WL3 is made of the wiring containing aluminum as the main component, and has the characteristics in which the resistance value is increased by the temperature rise. Therefore, according to the first typified aspect, in the condition where the temperature dependence of the drain current flowing through the nFET 10B has a larger influence than the temperature dependence of the gate voltage V_{g} of the power transistor 100, the change in the “turn-off time” is suppressed by the change in the interconnection resistance of the metal wiring WL2 and the change in the interconnection resistance of the metal wiring WL3, and, as a result, the “turn-off time” can be kept almost constant regardless of the temperature rise.

Next, the verification results will be described.

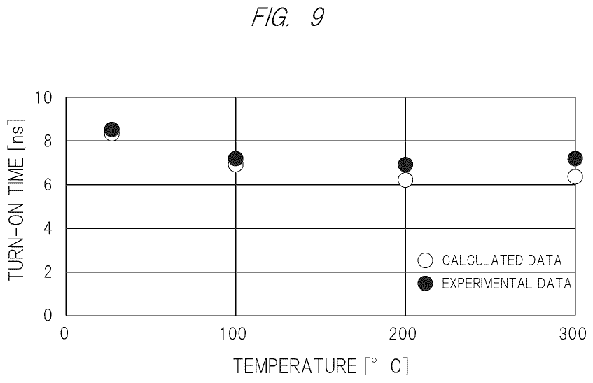

FIG. 9 is a graph showing the temperature dependence of “turn-on time”. In FIG. 9, the horizontal axis indicates the temperature (° C.), and the vertical axis indicates “turn-on time” (ns). A plot illustrated with a black circle is experimental data, while a plot illustrated with a white circle is calculated data.

In FIG. 9, in focusing on the experimental data, the “turn-on time” at around the room temperature (25° C.) is 8.5 ns, and the “turn-on time” is temporarily decreased to 7 ns by the temperature rise to around 200° C. After that, by the temperature rise from around 200° C. to around 300° C., the “turn-on time” is increased. Such behavior can be explained, for example, qualitatively below. That is, first, at 200° C. or lower, by the temperature rise, the gate voltage (the Miller plateau voltage) is decreased while the drain current of the pFET 10A is increased. As a result, for example, since the gate current of the power transistor 100 increases based on Equation 2, the “turn-on time” decreases based on Equation 1. This implies that the decrease in the “turn-on time” from 8.5 ns to 7 ns can be explained by the experimental data. Next, at 200° C. or higher, in the first typified aspect, the increase in the drain current of the pFET 10A is suppressed by the increase in the interconnection resistance of the metal wiring WL3 and the increase in the interconnection resistance of the metal wiring WL4. As a result, the gate current of the power transistor 100 decreases, thereby increasing the “turn-on time” based on Equation 1. In other words, the decrease in the “turn-off time” is suppressed by the increase in the interconnection resistance of the metal wiring WL3 and the increase in the interconnection resistance of the metal wiring WL4.

The behavior of the experimental data is explained as described above. Based on the experimental data, the behavior described above suppresses the change in the “turn-on time” to be within 18% when the temperature of the silicon carbide power semiconductor device 1 is in the range of 25° C. to 300° C.

Accordingly, according to the first typified aspect, it has been confirmed that the decrease in the “turn-on time” of the power transistor 100 due to the temperature change is suppressed by the increase in the resistance value of the resistance component (interconnection resistance of the metal wiring WL3 and interconnection resistance of the metal wiring WL4) electrically connected to the CMOS transistor due to the temperature change.

Note that the “turn-off time” is hardly changed even by the temperature change in the case of high-speed switching operation with a switching time of several nanoseconds. This is because the switching time is faster than the charging time to accumulate the charges in the output capacitance of the power transistor 100 and the Schottky barrier diode 110, and therefore, the “turn-off time” is rate-limited by the charging time. That is, for example, as shown in FIG. 5, in the silicon carbide power semiconductor device 1 in the first typified aspect, the semiconductor chip CHP1 on which the power transistor 100 is formed and the semiconductor chip CHP2 on which the CMOS transistor is formed are arranged close to each other, and, as a result, the high-speed switching operation (of several nanoseconds) is achieved. In this case, since the “turn-off time” has almost no temperature dependence, it can be the that it is not necessary to adopt the basic idea in which the change in the “turn-off time” is suppressed by the change in the interconnection resistance of the metal wiring WL2 and the change in the interconnection resistance of the metal wiring WL3.

Here, the “high-speed switching operation” is defined as a switching operation whose switching time is several nanoseconds or less (for example, 9 ns or less). For example, a switching time of 7 ns or more and 8 ns or less can be exemplified. In contrast, “low-speed switching operation” can be defined as a switching operation whose switching time is slower than that of the “high-speed switching operation”. For example, a switching operation whose switching time is on an order of several tens of nanoseconds (for example, 10 ns or more and 99 ns or less) can be exemplified.

When the switching time is several tens of nanoseconds, the “turn-off time” is also slower than the discharge time of the amount of charges, and therefore, the “turn-off time” is considered to have the temperature dependence without being rate-limited by the discharge time. Here, particularly, it is considered that the condition in which the temperature dependence of the drain current flowing through the nFET 10B has a larger influence than the temperature dependence of the gate voltage V_{g} of the power transistor 100 is satisfied. In this case, the configuration of the first typified aspect, which uses the interconnection resistance of the metal wiring WL3 electrically connected to the drain electrode DE1 of the nFET 10B and the metal wiring WL2 electrically connected to the source electrode SE1 of the nFET 10B as the resistance components electrically connected to the nFET 10B, is useful because the “turn-off time” can be kept almost constant regardless of the temperature rise.

### First Modification Example

FIG. 10 is a diagram showing the device structure in a first modification example. In FIG. 10, an n-type resistance element RD is provided together with the pFET 10A in the p-type silicon carbide substrate SUB. Here, the n-type resistance element RD has an n-type semiconductor region RN formed in the p-type silicon carbide substrate SUB and a pair of electrodes EA and EB electrically connected to the n-type semiconductor region RN. Then, the drain electrode DE2 of the pFET 10A and the electrode EA of the n-type resistance element RD are electrically connected by a wire to each other.

Thus, in the first modification example, for example, the resistance of the n-type semiconductor region RN configuring the n-type resistance element RD is used as the resistance component electrically connected to the pFET 10A. In this regard, in a silicon carbide semiconductor, the n-type semiconductor region RN has the characteristics in which the resistance value is increased by the temperature rise.

For this reason, according to the first modification example, the decrease in “turn-on time” in the power transistor 100 due to the temperature rise can be suppressed by the increase in the resistance value of the n-type semiconductor region RN configuring the n-type resistance element RD due to the temperature rise.

In the first modification example, the example in which the n-type resistance element RD is provided so as to be electrically connected to the drain electrode DE2 of the pFET 10A has been described. However, the configuration in the first modification example is not limited thereto, and the n-type resistance element RD may be provided so as to be electrically connected to the source electrode SE2 of pFET 10A. Furthermore, the first modification example may be configured so that the n-type resistance element RD electrically connected to the drain electrode DE2 and the n-type resistance element RD electrically connected to the source electrode SE2 are provided.

Although not illustrated, the resistance of the n-type semiconductor region RN configuring the n-type resistance element RD can be used as the resistance component electrically connected to the nFET 10B. At this time, if the condition in which the temperature dependence of the drain current flowing through the nFET 10B has a larger influence than the temperature dependence of the gate voltage V_{g} of the power transistor 100 is satisfied, the decrease in the “turn-off time” in the power transistor 100 due to the temperature rise is suppressed by the increase in the resistance value of the n-type semiconductor region RN configuring the n-type resistance element RD due to the temperature rise.

### Second Modification Example

Under the condition in which the temperature dependence of the drain current flowing through the nFET 10B has a larger influence than the temperature dependence of the gate voltage V_{g} of the power transistor 100, the basic idea regarding “turn-off time” is an idea in which the resistance component having the characteristics in which the resistance value is increased by the temperature rise is used as a resistance component electrically connected to the nFET 10B. In this regard, for example, as described in the above-described first modification example, the n-type resistance element RD can be used as the resistance component electrically connected to the nFET 10B.

However, in the nFET 10B, each of the source region SRN and the drain region DRN is made of an n-type semiconductor region. Therefore, even adjustment of sizes of the source region SRN and the drain region DRN to provide the resistance component can achieve the basic idea in which the resistance component (n-type semiconductor region) having the characteristics in which the resistance value is increased by the temperature rise is used as the resistance component electrically connected to the nFET 10B.

Specifically, FIG. 11 is a diagram showing the device structure in the second modification example.

As shown in FIG. 11, in the nFET 10B in the second modification example, the size of the source region SRN is increased, and the size of the drain region DRN is increased. In other words, a width of the source region SRN in the x direction and a width of the drain region DRN in the x direction are increased. By this manner, the parasitic resistance component of the source region SRN and the drain region DRN which are the n-type semiconductor regions can be adjusted. Thereby, according to the second modification example, the source region SRN and the drain region DRN can have the resistance component made of the n-type semiconductor region, and therefore, can be provided with the resistance component having the characteristics in which the resistance value is increased by the temperature rise. As a result, the decrease in the “turn-off time” in the power transistor 100 due to the temperature rise can be suppressed.

### <Second Typified Aspect>

In focusing on “turn-off time”, in the first typified aspect described above, it is assumed that the temperature dependence of the drain current flowing through the nFET 10B has a larger influence than the temperature dependence of the gate voltage V_{g} of the power transistor 100.

In this case, the decrease in the “turn-off time” in the power transistor 100 due to the temperature rise can be suppressed by using the resistance component having the characteristics in which the resistance value is increased by the temperature rise as the resistance component electrically connected to the nFET 10B. In contrast, in the configuration of the first typified aspect, it is difficult to suppress the increase in the “turn-off time” due to the temperature rise in the case where the temperature dependence of the gate voltage V_{g} of the power transistor 100 has a larger influence than the temperature dependence of the drain current flowing through the nFET 10B.

Therefore, in the second typified aspect, in the assumption that the temperature dependence of the gate voltage V_{g} of the power transistor 100 has a larger influence than the temperature dependence of the drain current flowing through the nFET 10B, a devisal point for suppressing the increase in “turn-off time” due to the temperature rise will be described.

In this regard, when the temperature dependence of the gate voltage V_{g} of the power transistor 100 has a larger influence than the temperature dependence of the drain current flowing through the nFET 10B, if the resistance component having the characteristics in which the resistance value is decreased by the temperature rise is used as the resistance component electrically connected to the nFET 10B, the increase in the “turn-off time” in the power transistor 100 due to the temperature rise can be suppressed (basic idea).

A typified example of this basic idea will be described below.

FIG. 12 is a diagram showing the device structure in the second typified aspect. In FIG. 12, a p-type resistance element RD2 is provided together with the nFET 10B in the p-type silicon carbide substrate SUB. At this time, the p-type resistance element RD2 has a p-type semiconductor region RP included in an n-type well NWL formed in the p-type silicon carbide substrate SUB, and a pair of electrodes EA2 and EB2 electrically connected to the p-type semiconductor region RP. And, the drain electrode DE1 of the nFET 10B and the electrode EA2 of the p-type resistance element RD2 are electrically connected by a wire to each other.

As described above, in the second typified aspect, for example, the resistance of the p-type semiconductor region RP configuring the p-type resistance element RD2 is used as the resistance component electrically connected to the nFET 10B. In this regard, in the silicon carbide semiconductor, the p-type semiconductor region RP has the characteristics in which the resistance value is decreased by the temperature rise.

In the silicon carbide semiconductor, aluminum (Al) is used as the p-type dopant. Although an ionization rate of the Al on the low temperature side near the room temperature is low, the ionization rate is increased by the temperature rise, and the amount of the hole carriers is increased to decrease the resistance value. Note that nitrogen (N) and phosphorus (P), which are n-type dopant of the silicon carbide semiconductor, do not behave like the Al dopant because of being sufficiently ionized even at the room temperature and emitting electrons.

For this reason, according to the second typified aspect, the increase in the “turn-off time” in the power transistor 100 due to the temperature rise can be suppressed by the decrease in the resistance value of the p-type semiconductor region RP configuring the p-type resistance element RD2 due to the temperature rise.

In the second typified aspect, the example in which the p-type resistance element RD2 is provided so as to be electrically connected to the drain electrode DE1 of the nFET 10B has been described. However, the configuration in the second typified aspect is not limited thereto, and the p-type resistance element RD2 may be provided so as to be electrically connected to the source electrode SE1 of the nFET 10B. Furthermore, the second typified aspect may be configured so that the p-type resistance element RD2 electrically connected to the drain electrode DE1 and the p-type resistance element RD2 electrically connected to the source electrode SE1 are provided.

### <Third Typified Aspect>

In the third typified aspect, an example of applying the basic ideas in the embodiment to a semiconductor device in which the power transistor 100 and the switching circuitry 200 (CMOS transistor) are formed on a single semiconductor chip will be described.

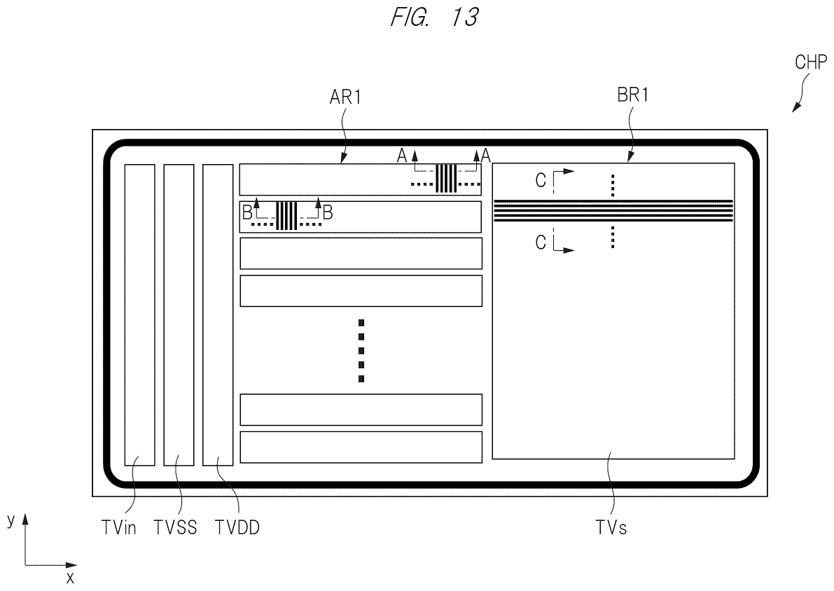

FIG. 13 is a diagram showing a layout of a semiconductor chip CHP in the third typified aspect.

In FIG. 13, the semiconductor chip CHP includes an input signal terminal TVin, a CMOS reference potential terminal TVSS, a CMOS power supply potential terminal TVDD, a power source terminal TVs, a CMOS region AR1 (switching circuitry region), and a power transistor region BR1.

In the x direction in FIG. 13, the CMOS region AR1 is arranged at the center of the semiconductor chip CHP, and the input signal terminal TVin, the CMOS reference potential terminal TVSS, and the CMOS power supply potential terminal TVDD are arranged on one side (left side) of the CMOS region AR1. In contrast, the power transistor region BR1 is arranged on the other side (right side) of the CMOS region AR1. Note that the power source terminal TVs is arranged above the power transistor inside the power transistor region BR1.

FIG. 14 is a diagram collectively showing respective cross-sectional views taken along the lines A-A, B-B, and C-C of FIG. 13, showing the device structure of the unit transistor in each region. Particularly, in FIG. 14, the region NAR is a region where the nFET 10B configuring the switching circuitry (CMOS transistor) is formed, and corresponds to the A-A cross-sectional view. In contrast, the region PAR is a region where the pFET 10A configuring the switching circuitry (CMOS transistor) is formed, and corresponds to the B-B cross-sectional view. Also, the region BR1 is a region where the power transistor 100 is formed, and corresponds to the C-C cross-sectional view.

### <<Device Structure of Power Transistor 100>>

As shown in FIG. 14, the semiconductor chip CHP includes the power transistor region BR1 and the CMOS region AR1. The power transistor 100 is formed in the power transistor region BR1, while the nFET 10B is formed in the region NAR of the CMOS region AR1. In addition, the pFET 10A is formed in the region PAR of the CMOS region AR1.

The power transistor 100 is made of a trench-gate power MOSFET having a gate, a source, and a drain. In contrast, the nFET 10B is made of a surface channel type MOSFET having a gate, a source, and a drain, and the pFET 10A is made of a buried channel type MOSFET having a gate, a source, and a drain.

The power transistor 100, the nFET 10B, and the pFET 10A are formed on a stacked semiconductor substrate SB.

The stacked semiconductor substrate SB has a drift layer (n-type semiconductor layer) DL formed on the semiconductor substrate SUB1, a buried base layer (p-type semiconductor layer) BBL formed on the drift layer DL, and a base layer (p-type semiconductor layer) BL formed on the buried base layer BBL.

The semiconductor substrate SUB1 is an n-type silicon carbide substrate, and its polytype is, for example, 4H. That is, the semiconductor substrate SUB1 is made of an n-type 4H-SiC substrate.

The drift layer DL is an n-type semiconductor layer and is made of an epitaxial layer formed on the semiconductor substrate SUB1 by an epitaxial growth method.

The buried base layer BBL is a p-type semiconductor layer formed on the drift layer DL by an epitaxial growth method and an ion implantation method. The film thickness of the buried base layer BBL is about 1 μm. The buried base layer BBL is made of a stacked structure of a buried base layer BBL1 and a buried base layer BBL2, and each film thickness of the buried base layer BBL1 and the buried base layer BBL2 is about 0.5 μm.

The base layer BL is a p-type semiconductor layer, and is, for example, an epitaxial layer formed on the buried base layer BBL by an epitaxial growth method. The film thickness of the base layer BL is thicker than that of the buried base layer BBL. And, the p-type impurity concentration of the base layer BL is lower than the p-type impurity concentration of the buried base layer BBL. In the base layer BL, the channel forming region for the power transistor 100 is formed in the power transistor region BR1, while the nFET 10B and the pFET 10A are formed in the CMOS region AR1.

Since the base layer BL is formed as the epitaxial layer by the epitaxial growth method, the base layer BL with the relatively thick film thickness can be formed without using a special ion implantation apparatus capable of outputting MeV-class ion implantation energy. In this manner, the degree of freedom in designing the withstand voltage in the CMOS region AR1 or the like can be improved.

The semiconductor substrate SUB1, the drift layer DL, and the base layer BL are provided over the entire region of the power transistor region BR1 and the CMOS region AR1. The buried base layer BBL is provided over the entire region in the CMOS region AR1, while it is selectively provided in the power transistor region BR1. A trench protecting region (p-type semiconductor region) TPR is provided at a bottom of a trench groove TG, and a JFET layer (n-type semiconductor layer) DLS1 and a JFET layer (n-type semiconductor layer) DLS2 are provided around the trench groove TG and the trench protecting region TPR.

In the power transistor region BR1, the buried base layer BBL is arranged in a region other than the region with the trench protecting region TPR, the JFET layer DLS1, and the JFET layer DLS2 provided therein. Also, on a back surface of the semiconductor substrate SUB1, the drain electrode ED is formed on the entire region of the power transistor region BR1 and the CMOS region AR1.

In the power transistor region BR1, a trench groove TG is formed so as to penetrate the source region RSU and the base layer BL from the surface of the stacked semiconductor substrate SB, and a gate insulating film GIU and a gate electrode EGU are formed inside the trench groove TG.

The gate insulating film GIU is, for example, a silicon oxide film formed by a CVD method. The gate electrode EGU is made of a polysilicon film containing an n-type impurity.

A source region (n-type semiconductor region) RSU and a p-type region (p-type semiconductor region) RPU are formed in the base layer BL. The source region RSU is arranged on both sides of the trench groove TG so as to sandwich the trench groove TG. The p-type region (p-type semiconductor region) RPU is arranged on the opposite side of the trench groove TG or the gate electrode EGU across the source region RSU. In other words, it also can be said that the p-type region RPU is arranged between the source regions RSU of the adjacent unit transistors. Also, the source region RSU and the p-type region RPU are electrically connected to the source electrode ESU.

The p-type impurity concentration of the trench protecting region (p-type semiconductor region) TPR provided at the bottom of the trench groove TG is equal to the p-type impurity concentration of the buried base layer BBL and higher than the p-type impurity concentration of the base layer BL. The trench protecting region (p-type semiconductor region) TPR is an electric field relaxation layer. The trench protecting region TPR is made of a structure in which the trench groove TG is wedged into the trench protecting region TPR at the bottom of the trench groove TG in order to moderate the concentration of electric field on the gate insulating film GIU at the bottom of the trench groove TG. That is, the depth of the trench groove TG is larger than the total film thickness of the base layer BL and the buried base layer BBL2 and smaller than the total film thickness of the base layer BL and the buried base layer BBL.

In the region between the drift layer DL and the base layer BL, the trench protecting region TPR is sandwiched by the JFET layer (n-type semiconductor layer) DLS1 while the trench groove TG is sandwiched by the JFET layer (n-type semiconductor layer) DLS2. Since the gate insulating film GIU is covered with the trench protecting region TPR at the bottom of the trench groove TG, the dielectric breakdown of the gate insulating film GIU can be prevented. Also, by optimizing the n-type impurity concentration of the JFET layer DLS1 and the JFET layer DLS2, the dielectric breakdown of the gate insulating film GIU can be prevented without increase in the JFET resistance.

Furthermore, since a buried base layer BBL having a p-type impurity concentration higher than the p-type impurity concentration of the base layer BL is provided between the drift layer DL and the base layer BL, the drain-source withstand voltage of the power transistor 100 can be improved.

In addition, since the base layer BL where the channel of the power transistor 100 is formed is made of the epitaxial layer having the low impurity concentration, high channel mobility can be ensured, thereby reducing the on-resistance of the power transistor 100. That is, since the buried base layer BBL and the base layer BL which have different p-type impurity concentrations are provided, the improvement of the drain-source withstand voltage and the reduction of the on-resistance can be achieved without being influenced by each other.

The power transistor 100 is configured as described above.

### <<Device Structure of CMOS Transistor>>

The nFET 10B has a source region (n-type semiconductor region) RSN and a drain region (n-type semiconductor region) RDN that are formed in the base layer BL, a channel region RCN provided between the source region RSN and the drain region RDN, and a gate electrode EGN formed on the channel region RCN via a gate insulating film GIN.

The nFET 10B is a surface channel type MOSFET. By application of a desired gate voltage to the gate electrode EGN, a channel is formed in the channel region RCN just below the interface between the base layer BL and the gate insulator GIN. The channel region RCN provided between the source region RSN and the drain region RDN of the nFET 10B is part of the p-type base layer BL, and no impurity for threshold voltage adjustment is ion-implanted into the channel region RCN, and therefore, the p-type impurity concentration of the channel region RCN is equal to the p-type impurity concentration of the base layer BL.

The pFET 10A is formed in an n-type well region (n-type semiconductor region) NW formed in the base layer BL. The pFET 10A has a source region (p-type semiconductor region) RSP and a drain region (p-type semiconductor region) RDP that are formed in the n-type well region NW, and a gate electrode EGP formed on the surface of the stacked semiconductor substrate SB via a gate insulating film GIP.

The pFET 10A is a buried channel type MOSFET and has a buried channel region EBC with a thickness of about 0.2 μm from the surface of the stacked semiconductor substrate SB. The buried channel region EBC is a p-type semiconductor region, and is a region to which no n-type impurity has been substantially ion-implanted, although the region is inside the n-type well NW. By application of a desired voltage to the gate electrode EGP, the channel is formed not just below the interface between the buried channel region EBC and the gate insulating film GIP but at a position deeper than the interface.

The n-type well region NW is made of an n-type well layer (n-type semiconductor layer) NW1, an n-type well layer (n-type semiconductor layer) NW2, and an n-type well layer (n-type semiconductor layer) NW3.

The n-type well layer NW1 is provided at a relatively deep position from the surface of the stacked semiconductor substrate SB, and an n-type well layer NW2 is provided on the n-type well layer NW1. The n-type well layer NW1 and the n-type well layer NW2 are formed by, for example, ion-implanting nitrogen ion into the base layer BL. The p-type impurity concentration of the buried channel region EBC is equal to the p-type impurity concentration of the base layer BL. Note that the p-type impurity concentration of the base layer BL means, for example, the p-type impurity concentration of the channel forming region of the power transistor 100.

The CMOS transistor is configured as described above.

### <<Application of Basic Idea>>

The basic idea can also be applied to the semiconductor device in the third typified aspect having the configuration described above. For example, a metal wiring can be used as a resistance component electrically connected to the CMOS transistor. Specifically, by intentionally extending the metal wiring, the interconnection resistance of the metal wiring can be used as the resistance component electrically connected to the CMOS transistor, and therefore, the temperature dependence of the drain current of the CMOS transistor configuring the switching circuitry can be compensated by the temperature dependence of the resistance component included in the switching circuitry. As a result, the temperature dependence of the switching time can be decreased.

Furthermore, even in the third typified aspect, as in the first modification example and the second modification example described above, not the interconnection resistance of the metal wiring but the resistance of the n-type semiconductor region or p-type semiconductor region of the silicon carbide semiconductor can be used. For example, an n-type resistance element or a p-type resistance element that is connected to the CMOS transistor can be provided as a configuration that typifies the basic idea in the third typified aspect.

### <Extension of Basic Idea>

In the typified aspect described above, the basic idea and the typified aspects of the basic idea has been described in the assumption that the temperature dependence of the drain current has the characteristics in which the drain current in the pFET 10A and an nFET 10B configuring the CMOS transistor is increased by the temperature rise.

However, depending on the manufacturing conditions of the CMOS transistor, assumed that the temperature dependence of the drain current has not the characteristics in which the drain current is increased by the temperature rise but the characteristics in which it is decreased by the temperature rise. Even in this case, the basic idea can be extended and applied.

For example, the “turn-on time” of the switching time is focused.

The gate current of the power transistor 100 during the “turn-on time” of the power transistor 100 is expressed by Equation 2 described above. Here, the gate current I_{g} shown in Equation 2 corresponds to the drain current of the pFET 10A, and the drain current flowing through the pFET 10A is decreased by the temperature rise. In contrast, Equation 2 includes the gate voltage (the Miller plateau voltage) V_{g}, and the gate voltage V_{g} is decreased by the temperature rise.

Thus, for the temperature dependence of the gate current I_{g} expressed by Equation 2, it is necessary to consider both the temperature dependence of the drain current flowing through the pFET 10A and the temperature dependence of the gate voltage V_{g} of the power transistor 100.

In this regard, the drain current flowing through the pFET 10A is decreased by the temperature rise, and the gate voltage V_{g} of the power transistor 100 is also decreased by the temperature rise. Therefore, the temperature dependence of the drain current behaves so that the gate current I_{g} is decreased by the temperature rise. In contrast, according to Equation 3, the temperature dependence of the gate voltage V_{g} behaves so that the gate current I_{g} is increased by the temperature rise. That is, the temperature dependence of the drain current flowing through the pFET 10A is the opposite characteristics to the temperature dependence of the gate voltage V_{g} of power transistor 100.

Therefore, if the temperature dependence of the drain current flowing through the pFET 10A has a larger influence than the temperature dependence of the gate voltage V_{g} of the power transistor 100, the gate current I_{g} changes to be decreased by the temperature rise.

In contrast, if the temperature dependence of the gate voltage V_{g} of the power transistor 100 has a larger influence than the temperature dependence of the drain current flowing through the pFET 10A, the gate current I_{g} changes to be increased by the temperature rise.

For this reason, the change in the gate current I_{g} due to the temperature rise can be decreased if the temperature dependence of the drain current flowing through the pFET 10A has a larger influence than the temperature dependence of the gate voltage V_{g} of the power transistor 100, and if the temperature dependence of the resistance component Rpw(T) (resistance component 20) of the switching circuitry 200 is the temperature dependence in which the resistance value is decreased by the temperature rise.

In contrast, the change in the gate current I_{g} due to the temperature rise can be decreased if the temperature dependence of the gate voltage V_{g} of the power transistor 100 has a larger influence than the temperature dependence of the drain current flowing through the pFET 10A, and if the temperature dependence of the resistance component Rpw(T) (resistance component 20) of the switching circuitry 200 is the temperature dependence in which the resistance value is increased by the temperature rise.

Based on the above, the (extended) basic idea for “turn-on time” needs to be divided into the case in which the temperature dependence of the drain current flowing through the pFET 10A has a larger influence than the temperature dependence of the gate voltage V_{g} of the power transistor 100 and the case in which the temperature dependence of the gate voltage V_{g} of the power transistor 100 has a larger influence than the temperature dependence of the drain current flowing through the pFET 10A.

And, in the case in which the temperature dependence of the drain current flowing through the pFET 10A has a larger influence than the temperature dependence of the gate voltage V_{g} of the power transistor 100, the (extended) basic idea for “turn-on time” is the idea in which the change in the gate current I_{g} due to the temperature rise can be decreased if the temperature dependence of the resistance component Rpw(T) (resistance component 20) of the switching circuitry 200 is the temperature dependence in which the resistance value is decreased by the temperature rise. In this case, the change in the “turn-on time” due to the temperature change can be decreased based on Equation 1.

In contrast, in the case in which the temperature dependence of the gate voltage V_{g} of the power transistor 100 has a larger influence than the temperature dependence of the drain current flowing through the pFET 10A, the (extended) basic idea for “turn-on time” is the idea in which the change in the gate current I_{g} due to the temperature rise can be decreased if the temperature dependence of the resistance component Rpw(T) (resistance component 20) of the switching circuitry 200 is the temperature dependence in which the resistance value is increased by the temperature rise. In this case, the change in the “turn-on time” due to the temperature change can be decreased based on Equation 1.

Next, the “turn-off time” of the switching time is focused.

The gate current I_{g} of the power transistor 100 expressed by Equation 3 corresponds to the drain current of the nFET 10B, and the drain current is decreased by the temperature rise. Also, Equation 3 includes the gate voltage (the Miller plateau voltage) V_{g}, and the gate voltage V_{g} is decreased by the temperature rise.

Thus, for the temperature dependence of the gate current I_{g} expressed by Equation 3, it is necessary to consider both the temperature dependence of the drain current flowing through the nFET 10B and the temperature dependence of the gate voltage V_{g} of the power transistor 100.

In this regard, the drain current flowing through the nFET 10B is decreased by the temperature rise, and the gate voltage V_{g} of the power transistor 100 is also decreased by the temperature rise. Therefore, according to Equation 3, both the temperature dependence of the drain current flowing through the nFET 10B and the temperature dependence of the gate voltage V_{g} of the power transistor 100 contribute to the state in which the gate current l_{g} of the power transistor 100 is decreased by the temperature rise. For this reason, even in consideration of not only the temperature dependence of the drain current but also the temperature dependence of the gate voltage V_{g}, if the temperature dependence of the resistance component Rnw(T) (resistance component 30) of the switching circuitry 200 is the temperature dependence in which the resistance value is decreased by the temperature rise, the change in the gate current I_{g} due to the temperature rise can be decreased.

From the above, the basic idea for “turn-off time” is the idea in which the change in the gate current I_{g} of the power transistor 100 due to the temperature rise can be decreased if the temperature dependence of the resistance component Rnw(T) (resistance component 30) of the switching circuitry 200 is the temperature dependence in which the resistance value is decreased by the temperature rise. In this case, according to Equation 1, the change in the “turn-off time” due to the temperature change can be decreased.

Based on the above, the basic idea can be extended and applied even when the temperature dependence of the drain current of the CMOS transistor configuring the switching circuitry 200 has not the characteristics: in which the drain current is increased by the temperature rise but the characteristics in which the drain current is decreased by the temperature rise.

In the foregoing, the embodiments have been described. However, it is needless to say that the embodiments are not limited to the foregoing, and various modifications can be made within the scope of the present application.

The embodiments include the following aspects.

### (Appendix 1)

In a semiconductor device including:
a power transistor using a semiconductor material having a larger bandgap than a bandgap of silicon; and
a switching circuitry controlling switching of the power transistor,
the switching circuitry includes:
a CMOS transistor using a semiconductor material having a larger bandgap than the bandgap of silicon; and
a resistance component electrically connected to the CMOS transistor, and
a change in switching time of the power transistor due to temperature change is suppressed by a change in a resistance value of the resistance component due to the temperature change.

### (Appendix 2): Corresponding to Extension of Basic Idea

In the semiconductor device described in the appendix 1,
the switching time is turn-on time of the power transistor, and
an increase in the turn-on time of the power transistor due to the temperature rise is suppressed by a change in the resistance component in which a resistance value is decreased by the temperature rise.

(Appendix 3): Corresponding to Extension of Basic Idea

In the semiconductor device described in the appendix 1,
the switching time is turn-on time of the power transistor, and
a decrease in the turn-on time of the power transistor due to the temperature rise is suppressed by a change in the resistance component in which a resistance value is increased by the temperature rise.

### (Appendix 4): Corresponding to Extension of Basic Idea

In the semiconductor device described in the appendix 1,
the switching time is turn-off time of the power transistor, and
an increase in the turn-off time of the power transistor due to the temperature rise is suppressed by a change in the resistance component in which a resistance value is decreased by the temperature rise.

### EXPLANATION OF REFERENCE CHARACTERS

1 Silicon carbide power semiconductor device
10A pFET
10B nFET
20 Resistance component
30 Resistance component
100 Power transistor
110 Schottky barrier diode
120 Load
130 External power supply
200 Switching circuitry
AR1 CMOS region
BBL Buried base layer
BBL1 Buried base layer
BBL2 Buried base layer
BCP p-type body contact region
BCN n-type body contact region
BL Base layer
BR1 Power transistor region
CHP Semiconductor chip
CHP1 Semiconductor chip
CHP2 Semiconductor chip
CHP3 Semiconductor chip
DE1 Drain electrode
DE2 Drain electrode
DL Drift layer
DLS1 JFET layer
DLS2 JFET layer
DRN Drain region
DRP Drain region
EA Electrode
EA2 Electrode
EB Electrode
EB2 Electrode
EBC Buried channel region
ED Drain electrode
EGU Gate electrode
EGN Gate electrode
EGP Gate electrode
GN Gate electrode
GIN Gate insulating film
GIP Gate insulating film
GIU Gate insulating film
GOX1 Gate insulating film
GOX2 Gate insulating film
GP Gate electrode
IL Insulating layer
NW n-type well region
NW1 n-type well layer
NW2 n-type well layer
NW3 n-type well layer
NWL n-type well
PL p-type buried region
RA Region
RCN Channel region
RD n-type resistance element
RD2 p-type resistance element
RDN Drain region
RDP Drain region
RN n-type semiconductor region
RP p-type semiconductor region
RPU p-type region
RSN Source Region
RSP Source Region
RSU Source Region
SB Stacked semiconductor substrate
SE1 Source electrode
SE2 Source electrode
SRN Source Region
SRP Source Region
SUB p-type silicon carbide substrate
SUB1 Semiconductor substrate
TE1 Terminal
TE2 Terminal
TE3 Terminal
TE4 Terminal
TE5 Terminal
TE6 Terminal
TG Trench groove
TPR Trench protecting region
WB Wiring board
WL1 Metal wiring
WL2 Metal wiring
WL3 Metal wiring
WL4 Metal wiring
WL5 Metal wiring

1. A semiconductor device comprising:
a power transistor including a semiconductor material having a larger bandgap than a bandgap of silicon; and
circuitry configured to control switching of the power transistor,
wherein the circuitry includes:
a Complementary Metal Oxide Semiconductor (CMOS) transistor including a semiconductor material having a larger bandgap than the bandgap of silicon; and
a resistance component electrically connected to the CMOS transistor, and
wherein a change in a switching time of the power transistor due to temperature change is reduced in response to a change in a resistance value of the resistance component caused by the temperature change.

2. The semiconductor device according to claim 1,
wherein the switching time is a turn-on time of the power transistor, and
wherein a decrease in the turn-on time of the power transistor due to a temperature rise is reduced in response to a change in the resistance component in which the resistance value is increased as a result of the temperature rise.

3. The semiconductor device according to claim 2,
wherein the CMOS transistor includes:
a p-channel field effect transistor connected to a power supply potential; and
an n-channel field effect transistor connected to a reference potential,
wherein a connection node is between a drain of the p-channel field effect transistor and a drain of the n-channel field effect transistor and is connected to a gate of the power transistor,
wherein a gate of the p-channel field effect transistor and a gate of the n-channel field effect transistor are electrically connected, and
wherein the resistance component included in the circuitry includes an interconnection resistance of a metal wiring electrically connected to the p-channel field effect transistor or a resistance of an n-type semiconductor.

4. The semiconductor device according to claim 2, wherein the turn-on time is several nanoseconds or less.

5. The semiconductor device according to claim 2, wherein a change in the turn-on time is 18% or less when a temperature of the semiconductor device is in a range of 25° C. to 300° C.

6. The semiconductor device according to claim 1,
wherein the switching time is a turn-off time of the power transistor, and
wherein a decrease in the turn-off time of the power transistor caused by a temperature rise is reduced in response to a change in the resistance component in which the resistance value is increased as a result of the temperature rise.

7. The semiconductor device according to claim 6,
wherein the CMOS transistor includes:
a p-channel field effect transistor connected to a power supply potential; and
an n-channel field effect transistor connected to a reference potential,
wherein a connection node is between a drain of the p-channel field effect transistor and a drain of the n-channel field effect transistor and is connected to a gate of the power transistor,
wherein a gate of the p-channel field effect transistor and a gate of the n-channel field effect transistor are electrically connected, and
wherein the resistance component included in the circuitry includes an interconnection resistance of a metal wiring connected to the n-channel field effect transistor or a resistance of an n-type semiconductor.

8. The semiconductor device according to claim 1,
wherein the switching time is a turn-off time of the power transistor, and
wherein an increase in the turn-off time of the power transistor caused by a temperature rise is reduced in response to a change in the resistance component in which the resistance value is decreased as a result of the temperature rise.

9. The semiconductor device according to claim 8,
wherein the CMOS transistor includes:
a p-channel field effect transistor connected to a power supply potential; and
an n-channel field effect transistor connected to a reference potential,
wherein a connection node is between a drain of the p-channel field effect transistor and a drain of the n-channel field effect transistor and is connected to a gate of the power transistor,
wherein a gate of the p-channel field effect transistor and a gate of the n-channel field effect transistor are electrically connected, and
wherein the resistance component included in the circuitry includes a resistance of a p-type semiconductor electrically connected to the n-channel field effect transistor.

10. The semiconductor device according to claim 6, wherein the turn-off time is on an order of several tens of nanoseconds.

11. The semiconductor device according to claim 1,
wherein the power transistor is on a first semiconductor chip,
wherein the CMOS transistor is on a second semiconductor chip, and
wherein the semiconductor material is silicon carbide.

12. The semiconductor device according to claim 1,
wherein the power transistor and the CMOS transistor are on a single semiconductor chip, and
wherein the semiconductor material is silicon carbide.

13. The semiconductor device according to claim 1,
wherein the power transistor is a power Metal Oxide Semiconductor Field Effect Transistor (MOSFET) or an Insulated Gate Bipolar Transistor (IGBT), and
wherein the semiconductor material is silicon carbide.

14. The semiconductor device according to claim 3,
wherein the power transistor is on a first semiconductor chip,
wherein the CMOS transistor is on a second semiconductor chip, and
wherein the semiconductor material is silicon carbide.

15. The semiconductor device according to claim 3,
wherein the power transistor and the CMOS transistor are on a single semiconductor chip, and
wherein the semiconductor material is silicon carbide.

16. The semiconductor device according to claim 3,
wherein the power transistor is a power MOSFET or an IGBT, and
wherein the semiconductor material is silicon carbide.
